(19) United States
(12) Patent Application Publication
(10) Pub. No.: US 2025/0312893 A1
(43) Pub. Date: Oct. 9, 2025

(54) PRESSING MEMBER AND HOLDING DEVICE

(71) Applicant: NHK SPRING CO. LTD., Yokohama-shi (JP)

(72) Inventors: Takashi Nidaira, Kanagawa (JP); Yuya Hironaka, Kanagawa (JP)

(73) Assignee: NHK SPRING CO. LTD., Yokohama-shi (JP)

(21) Appl. No.: 18/985,781

(22) Filed: Dec. 18, 2024

(30) Foreign Application Priority Data
Dec. 27, 2023 (JP) 2023-220903

(51) Int. Cl. B25B 5/16

(52) U.S. Cl. CPC B25B 5/163

(57) ABSTRACT

A pressing member for pressing a pressing target includes: a pressed portion configured to receive a load from an outside; and a pressing portion extending from the pressed portion and configured to be in contact with the pressing target and press the pressing target. The pressing portion is provided with a plurality of through holes penetrating the pressing portion in an extension direction and a hole portion extending in a direction intersecting a penetration direction of the through holes.

This application is based upon and claims the benefit of priority of the prior Japanese Patent Application No. 2023-220903, filed on Dec. 27, 2023, the entire contents of which are incorporated herein by reference.

### BACKGROUND

The present disclosure relates to a pressing member and a holding device.

In the related art, when a conduction state inspection or an operation characteristic inspection of an inspection target such as a semiconductor integrated circuit is performed, a plurality of contact probes are used to achieve electrical connection between the inspection target and a signal processing device having a circuit board that outputs an inspection signal. The plurality of contact probes are set in an inspection target holding device called a lid or housed in a socket (see, for example, Japanese Unexamined Patent Publication No. 2006-162254 and Japanese Examined Patent Publication No. H1-9735) At this time, the lid or the socket is provided with a pressing member that presses the inspection target against the contact probe. The pressing member is provided with a through hole through which a medium (liquid or gas) that heats or cools the inspection target passes, for example.

### SUMMARY

Meanwhile, as described in Japanese Unexamined Patent Publication No. 2006-162254 and Japanese Examined Patent Publication No. H1-9735, the through hole formed in the pressing member described above is provided in a center portion of the pressing member. At this time, when a size of the through hole is increased to improve the efficiency of heating or cooling, pressing against the inspection target may become unstable.

There is a need for a pressing member and a holding device capable of achieving both uniform pressing on a pressing target and efficient heating or cooling of the pressing target.

According to one aspect of the present disclosure, there is provided a pressing member for pressing a pressing target, including: a pressed portion configured to receive a load from an outside; and a pressing portion extending from the pressed portion and configured to be in contact with the pressing target and press the pressing target, wherein the pressing portion is provided with a plurality of through holes penetrating the pressing portion in an extension direction and a hole portion extending in a direction intersecting a penetration direction of the through holes.

According to another aspect of the present disclosure, there is provided a holding device including: a frame; a base plate configured to support the frame in a rollable manner; and a pressing member provided between the frame and the base plate and configured to press a pressing target, wherein the pressing member includes a pressed portion configured to receive a load from an outside, and a pressing portion extending from the pressed portion and configured to be in contact with the pressing target and press the pressing target, and the pressing portion includes a plurality of through holes penetrating the pressing portion in an extension direction, and a hole portion extending in a direction intersecting a penetration direction of the through holes.

### BRIEF DESCRIPTION OF THE DRAWINGS

FIG. 1 is a cross-sectional view illustrating a configuration of a lid according to an embodiment;

FIG. 2 is a (first) perspective view illustrating a configuration of a part of a pressing member included in the lid according to the embodiment;

FIG. 3 is a (second) perspective view illustrating a configuration of a part of the pressing member included in the lid according to the embodiment;

FIG. 4 is a (first) perspective view illustrating a configuration of a part of a pressing member included in a lid according to a first modification of the embodiment;

FIG. 5 is a (second) perspective view illustrating a configuration of a part of the pressing member included in the lid according to the first modification of the embodiment;

FIG. 6 is a (first) perspective view illustrating a configuration of a part of a pressing member included in a lid according to a second modification of the embodiment;

FIG. 7 is a (second) perspective view illustrating a configuration of a part of the pressing member included in the lid according to the second modification of the embodiment;

FIG. 8 is a (first) perspective view illustrating a configuration of a part of a known pressing member;

FIG. 9 is a (second) perspective view illustrating a configuration of a part of the known pressing member;

FIG. 10 is a (third) perspective view illustrating a configuration of a part of the known pressing member;

FIG. 11 is a (fourth) perspective view illustrating a configuration of a part of the known pressing member;

FIG. 12 is a diagram illustrating displacement of a pressing member and an inspection target at the time of pressing by the pressing member illustrated in FIGS. 2 and 3;

FIG. 13 is a diagram illustrating displacement of an inspection target at the time of pressing by the pressing member illustrated in FIGS. 2 and 3;

FIG. 14 is a diagram illustrating displacement of a pressing member and an inspection target at the time of pressing by the pressing member illustrated in FIGS. 4 and 5;

FIG. 15 is a diagram illustrating displacement of an inspection target at the time of pressing by the pressing member illustrated in FIGS. 4 and 5;

FIG. 16 is a diagram illustrating displacement of a pressing member and an inspection target at the time of pressing by the pressing member illustrated in FIGS. 6 and 7;

FIG. 17 is a diagram illustrating displacement of an inspection target at the time of pressing by the pressing member illustrated in FIGS. 6 and 7;

FIG. 18 is a diagram illustrating displacement of a pressing member and an inspection target at the time of pressing by the pressing member illustrated in FIGS. 8 and 9;

FIG. 19 is a diagram illustrating displacement of an inspection target at the time of pressing by the pressing member illustrated in FIGS. 8 and 9;

FIG. 20 is a diagram illustrating displacement of a pressing member and an inspection target at the time of pressing by the pressing member illustrated in FIGS. 10 and 11;

FIG. 21 is a diagram illustrating displacement of an inspection target at the time of pressing by the pressing member illustrated in FIGS. 10 and 11; and

FIG. 22 is a diagram illustrating a temporal change in temperature rise in each pressing member.

### DETAILED DESCRIPTION

Hereinafter, embodiments will be described in detail with reference to the drawings. Note that the present disclosure is not limited by the following embodiments. In addition, since each drawing referred to in the following description merely schematically illustrates a shape, a size, and a positional relationship to such an extent that the contents of the present disclosure may be understood, the present disclosure is not limited only to the shape, the size, and the positional relationship illustrated in each drawing.

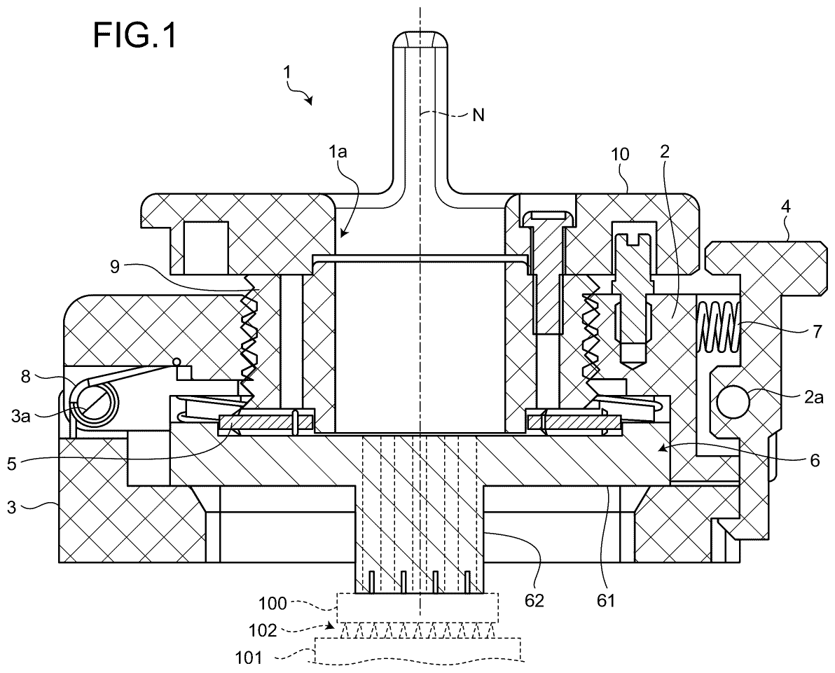

FIG. 1 is a cross-sectional view illustrating a configuration of a lid according to an embodiment. A lid 1 illustrated in FIG. 1 is a device used when an electrical characteristic inspection of a semiconductor integrated circuit 100 which is an inspection target is performed. The lid 1 presses the semiconductor integrated circuit 100 against a contact probe 102 held by a probe holder 101, and sends a medium for heating or cooling to the semiconductor integrated circuit 100 side to heat or cool the semiconductor integrated circuit 100. The contact probe 102 transmits an inspection signal output from a circuit board to the semiconductor integrated circuit 100.

The lid 1 includes a frame 2, a base plate 3, a latch 4, a bearing 5, a pressing member 6, a compression spring 7, a torsion spring 8, a bolt 9, and a handle 10.

The frame 2 is provided so as to be rotatable about a predetermined axis with respect to the base plate 3.

The base plate 3 is fixed to the inspection target (semiconductor integrated circuit 100) and the probe holder 101.

The frame 2 is biased in a direction away from the base plate 3 by the torsion spring 8.

The torsion spring 8 is attached to a shaft 3a formed on the base plate 3, and has one end fixed to the frame 2 and the other end fixed to the base plate 3.

The latch 4 is rotatably supported around a shaft 2a with respect to the frame 2. The latch 4 is locked to the base plate 3 to keep the frame 2 in pressure contact with the base plate 3. The latch 4 is biased by the compression spring 7 so as to rotate toward the base plate 3. Therefore, the latch 4 rolls, so that a locked state between the latch 4 and the base plate 3 changes. At this time, in a state where the latch 4 is locked to the base plate 3, the position of the frame 2 is fixed with respect to the base plate 3.

The bearing 5 supports the frame 2 and the bolt 9 such that the rotation of the bolt 9 about the axis is not transmitted to the frame 2 and the pressing member 6.

The pressing member 6 has one end in contact with the bolt 9 and the other end in contact with the inspection target (semiconductor integrated circuit 100) to be pressed. The pressing member 6 includes a pressed portion 61 that is in contact with the bolt 9 and receives a load from the bolt 9, and a pressing portion 62 that extends to the side of the pressed portion 61 opposite to the side in contact with the bolt 9 and presses the inspection target. The pressed portion 61 has a flat plate shape. The pressing portion 62 extends in a prismatic shape from a center portion of the pressed portion 61.

The pressing member 6 is formed using, for example, poly ether ether ketone (PEEK), copper, aluminum, alumite, ceramics, or the like. For example, a material in which copper is coated with nickel plating, aluminum and alumite are mixed, or characteristics are adjusted based on PEEK may be used.

The bolt 9 is screwed with the frame 2, and has one end in contact with the pressing member 6 and the other end provided with the handle 10. A user rotates the handle 10 to rotate the bolt 9 about the axis.

A through hole 1a penetrating the frame 2, the bolt 9, and the handle 10 in a direction of an axis N is formed in the frame 2, the bolt 9, and the handle 10. The axis N passes through the center of the pressing member 6.

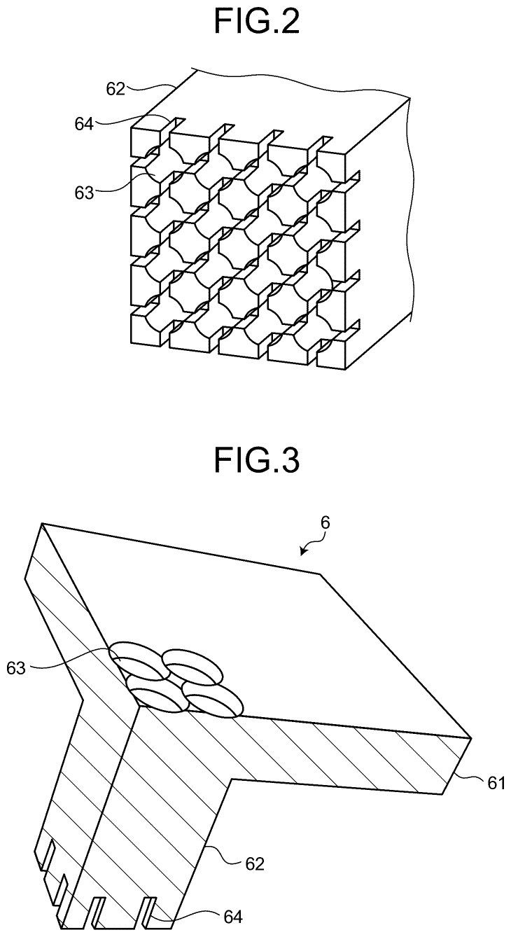

FIGS. 2 and 3 are perspective views illustrating a configuration of a part of the pressing member included in the lid according to the embodiment. FIG. 2 illustrates an end portion of the pressing portion 62 on a side opposite to a side connected to the pressed portion 61. FIG. 3 illustrates a configuration of a portion (¼) obtained by cutting the pressing member 6 into four equal parts.

In the pressing member 6, a plurality of (here, 16) through holes 63 penetrating an end surface of the pressed portion 61 on the side opposite to the pressing portion 62 side and an end surface of the pressing portion 62 on the side opposite to the pressed portion 61 side, and a plurality of (here, eight) slits 64 extending from an end surface of the pressing portion 62 on the side opposite to the pressed portion 61 side to a side surface connected to the end surface and extending in a direction orthogonal to a penetration direction of the through holes 63 are formed. The plurality of through holes 63 are arranged in a lattice pattern. For example, in each of the through holes 63, openings are arranged in a lattice pattern on both end surfaces of the pressing portion 62. Each of the slits 64 passes through the center of each of the intersecting through holes 63. The intersecting slits 64 extend in directions orthogonal to each other.

Although FIG. 3 illustrates an example in which the opening of the through hole 63 on the pressed portion 61 side has a tapered shape that increases in diameter toward the outside, the present disclosure is not limited to this shape, and the opening may have a uniform diameter, for example. In the present embodiment, an example in which the plurality of through holes 63 are arranged in a lattice pattern will be described, but the through holes may be arranged in a staggered lattice pattern, a partially intermittent lattice pattern, or a staggered lattice pattern, or may be arranged irregularly in accordance with the characteristics of the pressing target. Further, the intersecting slits 64 do not need to be orthogonal to each other, and an angle formed by the intersecting slits 64 may be set to an angle other than a right angle. Furthermore, the extension direction of the slit 64 is not limited to the direction orthogonal to the penetration direction of the through hole 63, and may be any direction as long as it intersects with the penetration direction of the through hole 63.

Here, at the time of heating or cooling the inspection target (semiconductor integrated circuit 100) through the lid 1, a medium (liquid or gas) is introduced through the through hole 1a. At this time, since the plurality of through holes 63 and the plurality of slits 64 are formed in the pressing member 6, the medium may be quickly and uniformly transmitted to the inspection target.

When the lid 1 pressurizes the inspection target toward the contact probe 102, the pressing portion 62 has a material portion (thick portion) between the through holes 63, and a portion other than the opening of the through hole 63 and the slit 64 forms a contact surface against the inspection target, so that a contact area is secured, and as a result, the inspection target may be uniformly pressed. The pressing portion 62 illustrated in FIG. 2 has contact surfaces arranged in a lattice pattern. By arranging the contact surfaces regularly as described above, it is possible to uniformly pressurize the pressing target.

According to the embodiment described above, uniform pressing to the inspection target may be realized by securing the material portion (thick portion) other than the portion where the through hole 63 and the slit 64 are formed, and efficient heating or cooling to the inspection target may be realized by forming the through hole 63 and the slit 64.

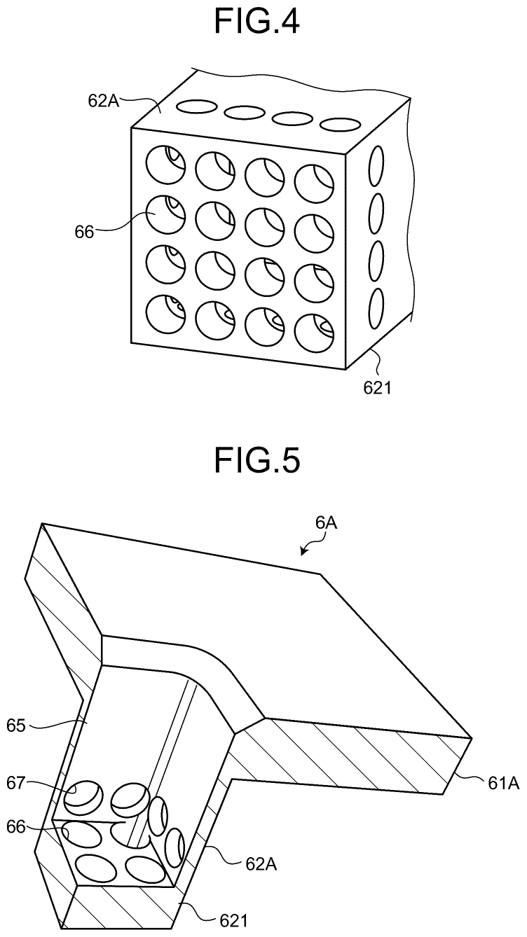

Next, a first modification of the present embodiment will be described with reference to FIGS. 4 and 5. FIGS. 4 and 5 are perspective views illustrating a configuration of a part of a pressing member included in a lid according to the first modification of the embodiment. The first modification is the same as the configuration of the above-described embodiment except that the configuration of the pressing member is changed in the lid 1 according to the embodiment. The same components as those in the above-described embodiment are denoted by the same reference numerals.

A pressing member 6A according to the first modification includes a pressed portion 61A that is in contact with the bolt 9 and receives a load from the bolt 9, and a pressing portion 62A that extends to the side of the pressed portion 61A opposite to the side in contact with the bolt 9 and presses the inspection target (semiconductor integrated circuit 100). The pressed portion 61A has a flat plate shape. The pressing portion 62A extends in a prismatic shape from the center portion of the pressed portion 61A.

FIG. 4 illustrates an end portion of the pressing portion 62A on the side opposite to the side connected to the pressed portion 61A. FIG. 5 illustrates a configuration of a portion (¼) obtained by cutting the pressing member 6A into four equal parts.

The pressing member 6A has a concave portion 65 forming a space extending from the pressed portion 61A toward the pressing portion 62A. That is, the pressing portion 62A has a bottomed cylindrical shape in which a space by the concave portion 65 and a bottom portion 621 provided on the side opposite to the pressed portion 61A side are formed. Note that the concave portion 65 forms a space connected to all of a plurality of first through holes 66 described later.

Further, the bottom portion 621 of the pressing portion 62A is formed with a plurality of (here, 16) first through holes 66 which are connected to the concave portion 65 and penetrate the bottom portion 621, and a plurality of (here, 16) second through holes 67 which are provided on a wall surface forming the concave portion 65 and penetrate the wall surface. The plurality of first through holes 66 are arranged in a lattice pattern. For example, in the first through holes 66, respective openings are arranged in a lattice pattern as viewed from an end surface of the pressing portion 62A on the side opposite to the pressed portion 61A side.

Although the example in which the second through hole 67 is located on the bottom portion 621 side is illustrated in FIGS. 4 and 5, the present disclosure is not limited to this position, and the second through hole 67 may be provided on a side surface connected to the end surface of the pressing portion 62A on the side opposite to the pressed portion 61A side, may be provided on the pressed portion 61A side, or may have a different position for each through hole.

Here, when the inspection target is heated or cooled through the lid according to the first modification, the medium (liquid or gas) is introduced through the through hole 1a. At this time, since the concave portion 65 and the plurality of first through holes 66 are formed in the pressing member 6A, the medium may be quickly and uniformly transmitted to the inspection target. In addition, since the second through hole 67 is formed, the circulation of the medium in the pressing member 6A is promoted, and the medium may be efficiently circulated.

Further, when the inspection target is pressurized toward the contact probe 102 by the lid, the pressing portion 62A has a thick portion between the first through holes 66 (here, the bottom portion 621), and a portion other than the opening of the first through hole 66 forms a contact surface with the inspection target, so that a contact area is secured, and as a result, the inspection target may be uniformly pressed.

According to the first modification described above, uniform pressing to the inspection target may be realized by securing the material portion (the thick portion; here, mainly the bottom portion 621) other than the portion where the concave portion 65 and the first through hole 66 are formed, and efficient heating or cooling to the inspection target may be realized by forming the concave portion 65, the first through hole 66, and the second through hole 67.

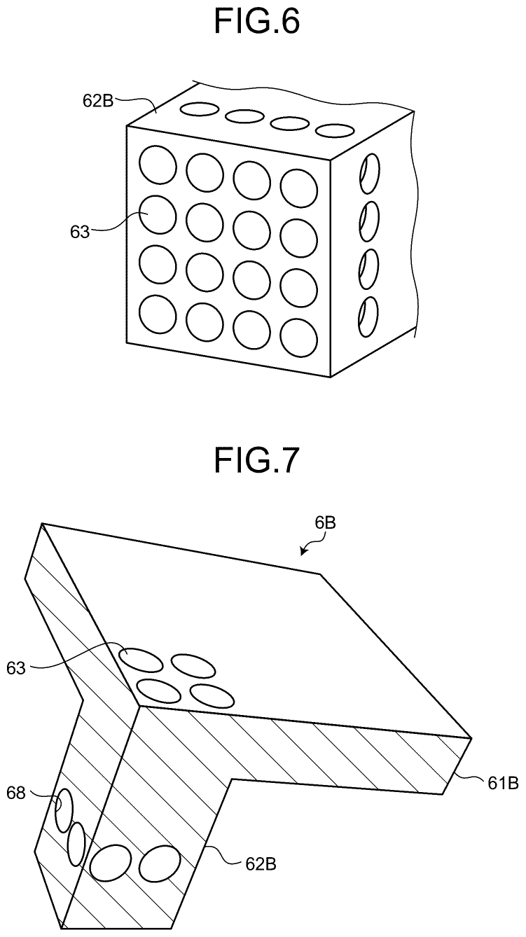

Next, a second modification of the present embodiment will be described with reference to FIGS. 6 and 7. FIGS. 6 and 7 are perspective views illustrating a configuration of a part of a pressing member included in a lid according to the second modification of the embodiment. The second modification is the same as the configuration of the above-described embodiment except that the configuration of the pressing member is changed in the lid 1 according to the embodiment. The same components as those in the above-described embodiment are denoted by the same reference numerals.

A pressing member 6B according to the second modification includes a pressed portion 61B that is in contact with the bolt 9 and receives a load from the bolt 9, and a pressing portion 62B that extends to the side of the pressed portion 61B opposite to the side in contact with the bolt 9 and presses the inspection target (semiconductor integrated circuit 100). The pressed portion 61B has a flat plate shape. The pressing portion 62B extends in a prismatic shape from the center portion of the pressed portion 61B.

FIG. 6 illustrates an end portion of the pressing portion 62B on the side opposite to the side connected to the pressed portion 61B. FIG. 7 illustrates a configuration of a portion (¼) obtained by cutting the pressing member 6B into four equal parts.

In the pressing member 6B, the through holes 63 (here, referred to as first through holes 63) and a plurality of (here, eight) second through holes 68 formed in the pressing portion 62B and penetrating the pressing portion 62B in a direction orthogonal to the penetration direction of the first through holes 63 are formed. The second through hole 68 is formed in a side surface connected to an end surface of the pressing portion 62B on the side opposite to the pressed portion 61B side.

Although FIGS. 6 and 7 illustrate an example in which the second through hole 68 is located on the end portion side of the pressing portion 62B on the side opposite to the pressed portion 61B side, the present disclosure is not limited to this position, and the second through hole 68 may be located on the pressed portion 61B side or may be located at a different position for each through hole.

Here, when the inspection target (semiconductor integrated circuit 100) is heated or cooled through the lid according to the second modification, the medium (liquid or gas) is introduced through the through hole 1a. At this time, since the plurality of first through holes 63 are formed in the pressing member 6B, the medium may be quickly and uniformly transmitted to the inspection target (semiconductor integrated circuit 100). In addition, since the second through hole 68 is formed, the circulation of the medium in the pressing member 6B is promoted, and the medium may be efficiently circulated.

When the inspection target (semiconductor integrated circuit 100) is pressurized toward the contact probe 102 by the lid, the pressing portion 62B has a thick portion between the first through holes 63, and a portion other than the opening of the first through hole 63 forms a contact surface with the inspection target, so that the inspection target (semiconductor integrated circuit 100) may be uniformly pressed.

According to the second modification described above, uniform pressing to the inspection target may be realized by securing the thick portion other than the portion where the first through hole 63 are formed, and efficient heating or cooling to the inspection target may be realized by forming the first through hole 63 and the second through hole 68.

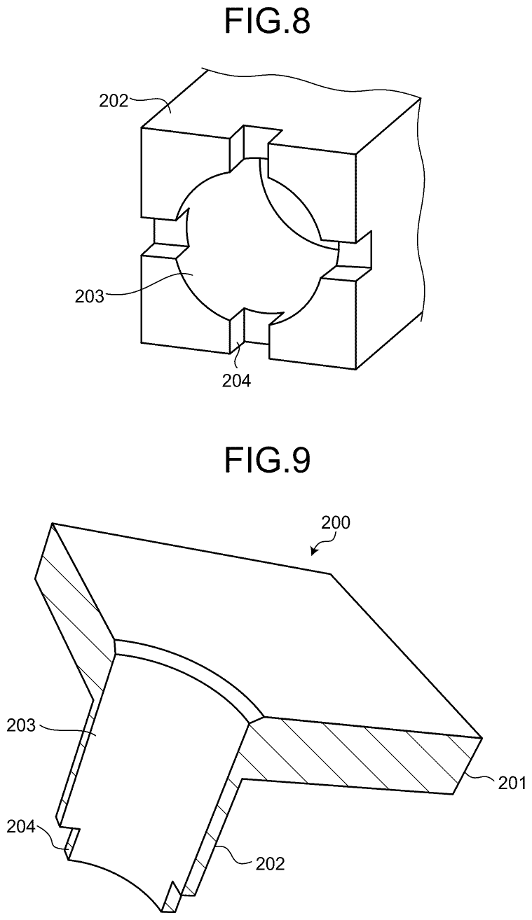

Hereinafter, an example in which displacement at the time of pressing an inspection target and a temperature rise at the time of heating are analyzed for pressing members according to the embodiment, the first and second modifications, and a comparative example will be described with reference to FIGS. 8 to 22. In the description of the lid, components other than the pressing member are the same.

### Comparative Example 1

FIGS. 8 and 9 are perspective views illustrating a configuration of a part of a known pressing member.

A pressing member 200 according to Comparative Example 1 includes a pressed portion 201 that is in contact with the bolt 9 and receives a load from the bolt 9, and a pressing portion 202 that extends to the side of the pressed portion 201 opposite to the side in contact with the bolt 9 and presses the inspection target. The pressed portion 201 has a flat plate shape. The pressing portion 202 extends in a prismatic shape from the center portion of the pressed portion 201.

FIG. 8 illustrates an end portion of the pressing portion on the side opposite to the side connected to the pressed portion. FIG. 9 illustrates a configuration of a portion (¼) obtained by cutting the pressing member into four equal parts. The pressing member 200 is provided with a through hole 203 that penetrates an end surface of the pressed portion 201 on the side opposite to the pressing portion 202 side and an end surface of the pressing portion 202 on the side opposite to the pressed portion 201 side, and a plurality of (here, four) slits 204 that are provided at an end portion of the pressing portion 202 on the side opposite to the pressed portion 201 side and extend in a direction orthogonal to a penetration direction of the through hole 203. The through hole 203 forms an opening having a diameter equal to or longer than half the length of one side of a rectangle formed by an outer edge in a cross section having a plane orthogonal to the extension direction of the pressing portion 202 as a cut surface. In the respective slits 204, straight lines extending in the extension direction of the slits 204 pass through the center of the through hole 203, for example.

### Comparative Example 2

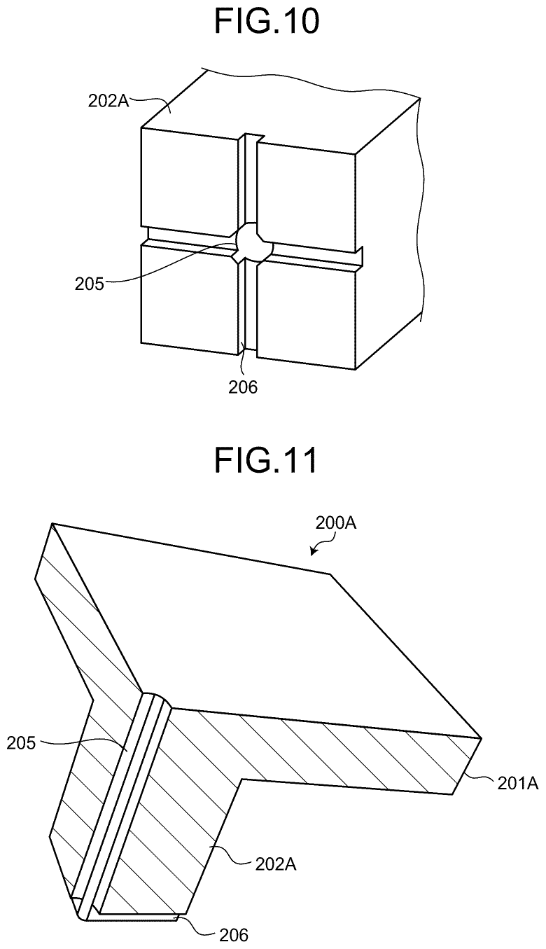

FIGS. 10 and 11 are perspective views illustrating a configuration of a part of a known pressing member.

A pressing member 200A according to Comparative Example 2 includes a pressed portion 201A that is in contact with the bolt 9 and receives a load from the bolt 9, and a pressing portion 202A that extends to the side of the pressed portion 201A opposite to the side in contact with the bolt 9 and presses the inspection target. The pressed portion 201A has a flat plate shape. The pressing portion 202A extends in a prismatic shape from the center portion of the pressed portion 201A.

FIG. 10 illustrates an end portion of the pressing portion on the side opposite to the side connected to the pressed portion. FIG. 11 illustrates a configuration of a portion (¼) obtained by cutting the pressing member into four equal parts. The pressing member 200A is provided with a through hole 205 that penetrates an end surface of the pressed portion 201A on the side opposite to the pressing portion 202A side and an end surface of the pressing portion 202A on the side opposite to the pressed portion 201A side, and a plurality of (here, four) slits 206 that are provided at an end portion of the pressing portion 202A on the side opposite to the pressed portion 201A side and extend in a direction orthogonal to a penetration direction of the through hole 205. The through hole 205 forms an opening having a diameter less than half the length of one side of a rectangle formed by an outer edge in a cross section having a plane orthogonal to the extension direction of the pressing portion 202A as a cut surface. In the respective slits 206, straight lines extending in the extension direction of the slits 206 pass through the center of the through hole 205, for example.

Hereinafter, an example of analyzing displacement of the pressing member and the inspection target when a surface of the inspection target (model 400) opposite to the pressing member side is pressurized at 1.54 MPa will be described.

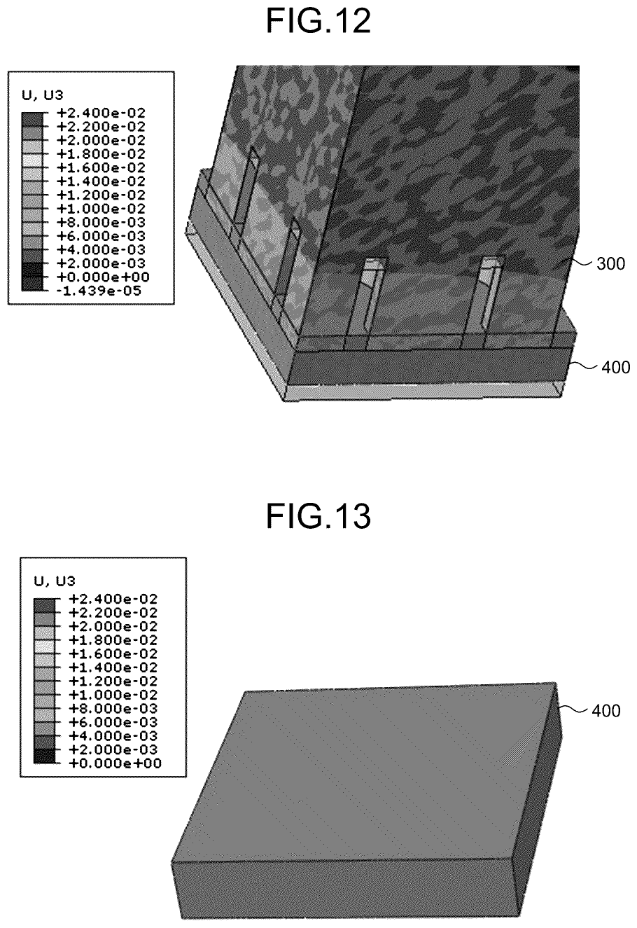

FIG. 12 is a diagram illustrating displacement of the pressing member and the inspection target at the time of pressing by the pressing member illustrated in FIGS. 2 and 3. FIG. 13 is a diagram illustrating displacement of the inspection target at the time of pressing by the pressing member illustrated in FIGS. 2 and 3. In FIGS. 12 and 13, for a model 300 corresponding to the pressing member 6 illustrated in FIGS. 2 and 3 and a model 400 corresponding to the inspection target, the displacement of the vicinity of the end portion of the pressing member on the inspection target side and the inspection target at the time of pressing is illustrated.

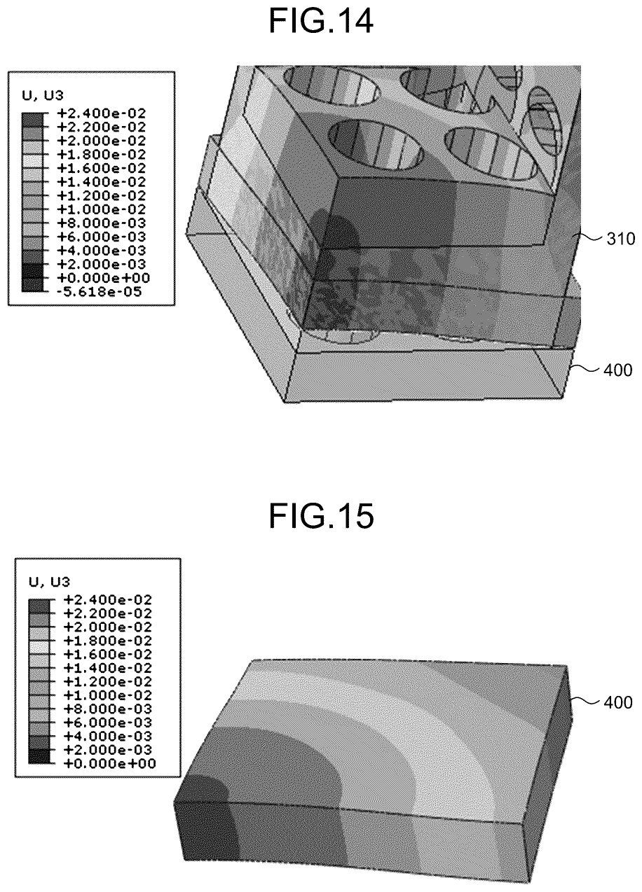

FIG. 14 is a diagram illustrating displacement of the pressing member and the inspection target at the time of pressing by the pressing member illustrated in FIGS. 4 and 5. FIG. 15 is a diagram illustrating displacement of the inspection target at the time of pressing by the pressing member illustrated in FIGS. 4 and 5. In FIGS. 14 and 15, for a model 310 corresponding to the pressing member 6A illustrated in FIGS. 4 and 5 and a model 400 corresponding to the inspection target, displacement of the vicinity of the end portion of the pressing member on the inspection target side and the inspection target at the time of pressing is illustrated.

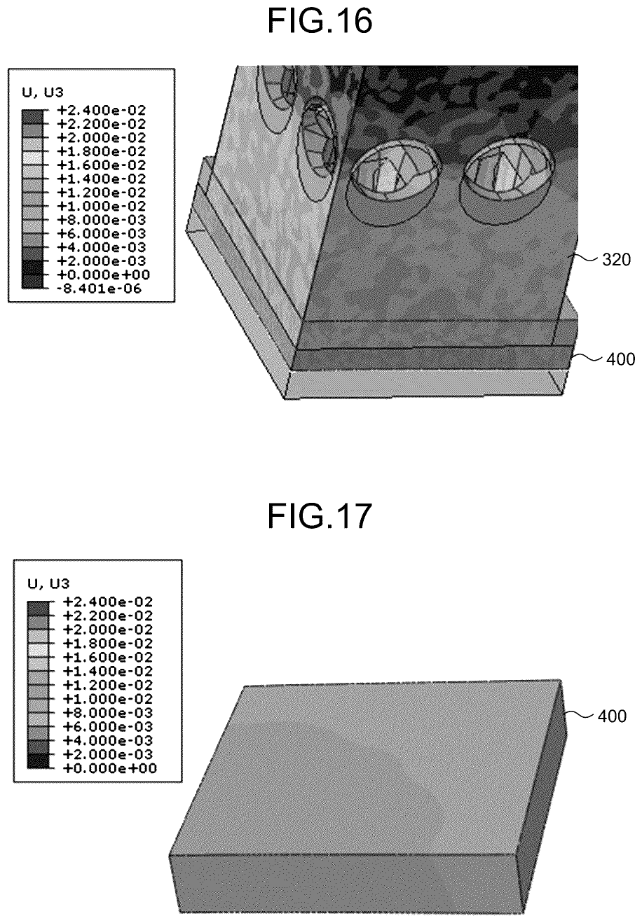

FIG. 16 is a diagram illustrating displacement of the pressing member and the inspection target at the time of pressing by the pressing member illustrated in FIGS. 6 and 7. FIG. 17 is a diagram illustrating displacement of the inspection target at the time of pressing by the pressing member illustrated in FIGS. 6 and 7. In FIGS. 16 and 17, for a model 320 corresponding to the pressing member 6B illustrated in FIGS. 6 and 7 and a model 400 corresponding to the inspection target, displacement of the vicinity of the end portion of the pressing member on the inspection target side and the inspection target at the time of pressing is illustrated.

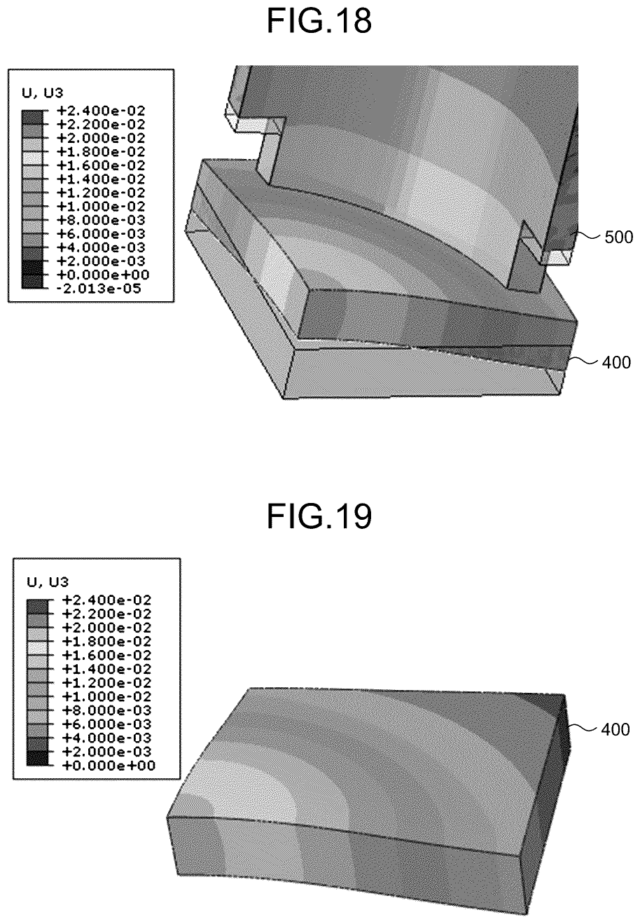

FIG. 18 is a diagram illustrating displacement of the pressing member and the inspection target at the time of pressing by the pressing member illustrated in FIGS. 8 and 9. FIG. 19 is a diagram illustrating displacement of the inspection target at the time of pressing by the pressing member illustrated in FIGS. 8 and 9. In FIGS. 18 and 19, for a model 500 corresponding to the pressing member 200 (Comparative Example 1) illustrated in FIGS. 8 and 9 and a model 400 corresponding to the inspection target, displacement of the vicinity of the end portion of the pressing member on the inspection target side and the inspection target at the time of pressing is illustrated.

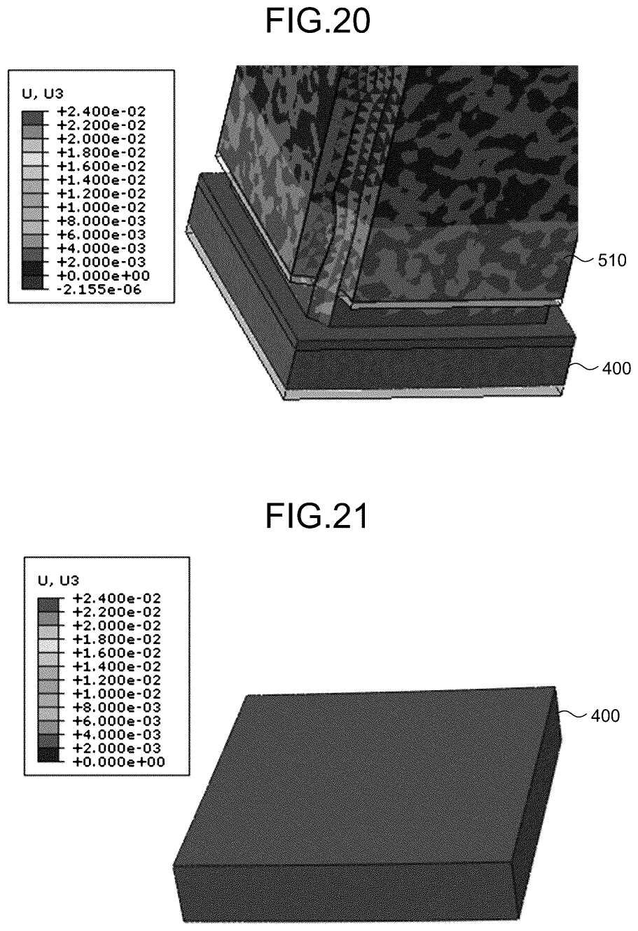

FIG. 20 is a diagram illustrating displacement of the pressing member and the inspection target at the time of pressing by the pressing member illustrated in FIGS. 10 and 11. FIG. 21 is a diagram illustrating displacement of the inspection target at the time of pressing by the pressing member illustrated in FIGS. 10 and 11. In FIGS. 20 and 21, for a model 510 corresponding to the pressing member 200A (Comparative Example 2) illustrated in FIGS. 10 and 11 and a model 400 corresponding to the inspection target, displacement of the vicinity of the end portion of the pressing member on the inspection target side and the inspection target at the time of pressing is illustrated.

As illustrated in FIGS. 20 and 21, when the inspection target is pressed using the pressing portion 202A having a large contact area with the inspection target, a load is uniformly applied to the inspection target, and displacement of the pressing member 200A and the inspection target at the time of pressing is small.

On the other hand, as illustrated in FIGS. 18 and 19, when the inspection target is pressed using the pressing portion 202 having a small contact area with the inspection target, a load applied to the inspection target becomes non-uniform, and displacement of the pressing member 200 and the inspection target at the time of pressing increases.

On the other hand, as illustrated in FIGS. 12 to 17, the displacement of the pressing members 6, 6A, and 6B according to the present embodiment and the first and second modifications is equal to that of Comparative Example 2 or smaller than that of Comparative Example 1. In the model 310 (pressing member 6A) and the model 400 (inspection target) illustrated in FIGS. 14 and 15, a maximum value of the displacement is large, but the inspection target is displaced as a whole, and the difference between the maximum displacement and the minimum displacement is smaller than the displacement amount of the inspection target illustrated in FIG. 19.

From these analysis results, it can be said that the pressing members according to the present embodiment and the first and second modifications may more uniformly press the inspection target than the pressing member according to Comparative Example 1.

Next, an example of analyzing heat spread (heat distribution) when the inspection target is heated through the pressing member will be described.

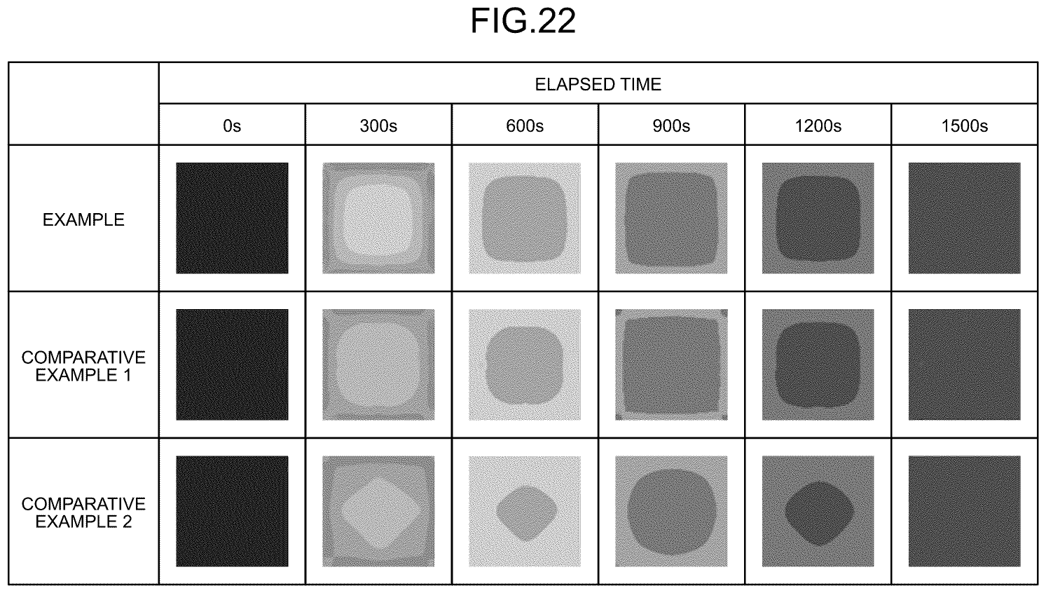

FIG. 22 is a diagram illustrating a temporal change in temperature rise in each pressing member. FIG. 22 illustrates temperature changes of Example (pressing member 6 according to the present embodiment: see FIGS. 2 and 3), Comparative Example 1 (pressing member 200: see FIGS. 8 and 9), and Comparative Example 2 (pressing member 200A: see FIGS. 10 and 11).

Here, it can be seen that when the inspection target is heated using the pressing portion 202 having a large opening of the through hole (Comparative Example 1), the heat spreads faster than when the pressing portion 202A having a small opening of the through hole is used (Comparative Example 2).

On the other hand, it can be seen that the pressing member 6 according to the present embodiment (Example) spreads heat faster than those in Comparative Examples 1 and 2.

From these analysis results, it can be said that the pressing member according to the present embodiment may heat the inspection target faster than the pressing member according to Comparative Example 1. In addition, in the pressing members according to the first and second modifications, since the space by the through hole or the like is secured similarly to the pressing member according to the embodiment, it can be said that the inspection target may be heated as much as or more than the pressing member according to Comparative Example 1.

According to the analysis results described above, it can be said that the pressing members according to the present embodiment and the first and second modifications may achieve both uniform pressing on the inspection target and efficient heating or cooling of the pressing target as compared with Comparative Examples 1 and 2.

Although the embodiments have been described, the present disclosure should not be limited only by the above-described embodiments. In the above-described embodiments and first and second modifications, an example in which the penetration directions of the through holes are parallel to each other has been described, but the through holes may be formed such that the penetration directions of the through holes are different from each other. The configuration of the lid described in the embodiment is merely an example, and various types of known lids may be applied. Further, the pressing member according to the present embodiment or the modification may be adopted in another holding device such as a socket or a handler.

As described above, the present disclosure may include various embodiments and the like that are not described herein, and various design changes and the like may be made without departing from the technical idea specified by the claims.

As described above, the pressing member and the holding device according to the present disclosure are suitable for achieving both uniform pressing on the pressing target and efficient heating or cooling of the pressing target.

According to the present disclosure, it is possible to achieve both uniform pressing on a pressing target and efficient heating or cooling of the pressing target.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiments have been described in detail, it should be understood that the various changes, substitutions, and alterations could be made hereto without departing from the spirit and scope of the disclosure.

What is claimed is:

1. A pressing member for pressing a pressing target, comprising:
a pressed portion configured to receive a load from an outside; and
a pressing portion extending from the pressed portion and configured to be in contact with the pressing target and press the pressing target, wherein
the pressing portion is provided with a plurality of through holes penetrating the pressing portion in an extension direction and a hole portion extending in a direction intersecting a penetration direction of the through holes.

2. The pressing member according to claim 1, wherein the plurality of through holes are arranged in a lattice pattern.

3. The pressing member according to claim 1, wherein the hole portion is a slit formed in an end surface of the pressing portion.

4. The pressing member according to claim 1, wherein the hole portion is a through hole formed in a side surface connected to an end surface of the pressing portion.

5. The pressing member according to claim 1, comprising
a concave portion forming a space extending from the pressed portion to the pressing portion side, wherein
the pressing portion has a bottomed cylindrical shape in which a space is formed by the concave portion and which has a bottom portion provided on a side opposite to the pressed portion side, and
the hole portion is formed in a wall surface forming the concave portion.

6. A holding device comprising:
a frame;
a base plate configured to support the frame in a rollable manner; and
a pressing member provided between the frame and the base plate and configured to press a pressing target, wherein
the pressing member includes
a pressed portion configured to receive a load from an outside, and
a pressing portion extending from the pressed portion and configured to be in contact with the pressing target and press the pressing target, and
the pressing portion includes
a plurality of through holes penetrating the pressing portion in an extension direction, and
a hole portion extending in a direction intersecting a penetration direction of the through holes.
